(19) United States
(12) Patent Application Publication
(10) Pub. No.: US 2017/0314587 A1
(43) Pub. Date: Nov. 2, 2017

(54) FLUID FLOW STRAIGHTENING MEMBER

(71) Applicant: IBIDEN CO., LTD., OGAKI-SHI, GIFU (JP)

(72) Inventor: Takashi TAKAGI, IBI-GUN, GIFU (JP)

(21) Appl. No.: 15/526,037

(22) PCT Filed: Nov. 11, 2015
(86) PCT No.: PCT/JP2015/081729

§ 371 Date: May 11, 2017

(30) Foreign Application Priority Data
Nov. 11, 2014 (JP) 2014-228830

(51) Int. Cl. F15D 1/00; B32B 1/08; B32B 18/00; C23C 16/44

(52) U.S. Cl. CPC F15D 1/00; C23C 16/4418; B32B 1/08; B32B 18/00

(57) ABSTRACT

There is provided a manufacturing method of a fluid flow straightening member having a structure in which disturbance of an air flow does not easily arise. In at least one of outermost layers of an outer circumferential surface or an inner circumferential surface which configures a tubular portion of the fluid flow straightening member, ceramic fibers are oriented in a direction along a plane including a central axis which is surrounded by the tubular portion.

### TECHNICAL FIELD

The present invention relates to a fluid flow straightening member which uses a fiber-reinforced ceramic composite material.

### BACKGROUND ART

Since fiber-reinforced ceramic composite materials have heat resistance, strength, and toughness, fiber-reinforced ceramic composite materials are used in various fields.

A fiber-reinforced ceramic composite material may be used as a fluid flow straightening member for a high-temperature, high-speed fluid by utilizing its high heat resistance and strength.

The fiber-reinforced ceramic composite material is a material which is obtained by adding ceramic fibers as an aggregate to a base material (a matrix) which is formed of ceramic. Although the ceramic which is the base material has heat resistance and strength, the ceramic is a brittle material due to the characteristics of a ceramic material having a high elastic modulus. The fiber-reinforced ceramic composite material is a material which is improved in brittleness, which is a weak point of the base material formed of ceramic, by further combining ceramic fibers.

Patent Literature 1 describes a carbon part formed of a carbon fiber-reinforced carbon composite material which is a fiber-reinforced ceramic composite material. The carbon part is characterized by including a base member which includes a deposition layer in which carbon fibers are deposited in layers and a coating layer which includes a high purity and hard material which covers the surface of the base member. Specifically, a gas flow straightening member for a semiconductor manufacturing apparatus is described.

The gas flow straightening member is, in a semiconductor manufacturing apparatus, a member for straightening the flow of an inert gas which is introduced via an introduction portion and reliably guiding the inert gas into a quartz crucible.

The carbon part is manufactured through a coating layer forming process in which a slurry in which carbon fibers are suspended in a liquid is suction molded, dried, fired, and purified, and subsequently, a coating layer which is formed of pyrolytic carbon is formed on a surface thereof.

Therefore, in addition to having heat resistance, strength and chemical stability, since no elements which become impurities in semiconductors are contained, it is favorably used as a gas flow straightening member for a semiconductor manufacturing apparatus.

### CITATION LIST

### Patent Literature

[Patent Literature 1] JP-A-2002-68851

### SUMMARY OF INVENTION

### Technical Problem

However, the aforementioned carbon part (the fiber-reinforced ceramic composite material) is given a shape by a mold which is used in suction molding, and is released from the mold after the suction molding. Therefore, the carbon part deforms easily in the process of drying, firing and purification, and unevenness forms easily on the surface.

Further, since the base member itself is a porous material in the first place, the base member has fine unevenness derived from the carbon fibers on the surface.

If a member which is in contact with a fluid, such as a fluid flow straightening member, has such unevenness on the surface, the member disturbs the flow of the gas and becomes a resistance.

In view of the above-described problem, an object of the present invention is to provide a fluid flow straightening member having a structure that does not easily disturb an air flow.

### Solution to Problem

The fluid flow straightening member of the present invention for solving the problem is a fluid flow straightening member including a tubular portion which surrounds a central axis, wherein the tubular portion includes a support material which includes an inner ceramic fiber layer and an outermost ceramic fiber layer, and a ceramic matrix which covers the support material, and wherein the outermost ceramic fiber layer which covers an outside and/or an inside of the inner ceramic fiber layer is configured by ceramic fibers which are oriented along the central axis.

The outermost ceramic fiber layer of the fluid flow straightening member is configured by the ceramic fibers which are oriented along the central axis. Therefore, since undulations which obstruct the flow of the fluid are not easily formed and a disturbance does not easily arise in the fluid, it is possible to reduce resistance.

Here, the flow of the fluid refers to a case in which a fluid moves relative to the fluid flow straightening member, and includes a case in which a fluid flows relative to the fluid flow straightening member and a case in which the fluid flow straightening member moves in the fluid.

According to the fluid flow straightening member of the present invention, since it is possible to reduce the unevenness which becomes a resistance of the air flow without processing the surface, it is possible to sufficiently exhibit the strength of a support material without cutting the ceramic fibers, and a high-strength fiber-reinforced ceramic composite material is obtained.

Favorable aspects of the fluid flow straightening member of the present invention will be described hereinafter.

(1) An angle between the ceramic fiber which configure the outermost ceramic fiber layer and a plane including the central axis is 0° to 20°.

Therefore, in the fluid flow straightening member of the present invention, when the angle between the plane including the central axis and the ceramic fiber is 0° to 20°, the air flow is capable of smoothly flowing along the ceramic fibers.

Further, since the unevenness caused by the thickness of the ceramic fiber is stretched in the direction of the central axis by greater than or equal to 1/sin 20° times (2.92 times), it is possible to reduce disturbance of the fluid and it is possible to reduce resistance.

(2) Both end portions of the tubular portion along the central axis are opened.

In the fluid flow straightening member of the present invention, since both end portions of the tubular portion along the central axis are opened, it is possible to allow the fluid to smoothly flow along the outer circumferential surface and the inner circumferential surface of the tubular portion. Therefore, the fluid flow straightening member of the present invention can be used as piping through the inner portion of which a fluid flows, a flying object and a propelling body which moves inside a fluid, or the like.

(3) The outermost ceramic fiber layer which covers the outside of the inner ceramic fiber layer is oriented along the central axis, and at least one of both end portions of the tubular portion along the central axis includes a cap portion and is closed.

In the fluid flow straightening member of the present invention, since the outermost ceramic fiber layer which covers the outside of the inner ceramic fiber layer is oriented along the central axis, and at least one of both end portions of the tubular portion along the central axis includes the cap portion and is closed, it is possible to allow the fluid to smoothly flow along the outer circumferential surface of the tubular portion. Therefore, it is possible to use the fluid flow straightening member of the present invention as a flying object and the like which moves inside a fluid.

(4) A contour shape of another end surface of the tubular portion is larger than a contour shape of one end surface of the tubular portion.

Since the tubular portion has a shape in which the contour shape of the other end surface is larger than the contour shape of the one end surface, the fluid flow straightening member of the present invention has a shape similar to, for example, a cone, a truncated cone, a spheroid, or the like. Since the sectional area of such a shape smoothly changes, it is possible to suppress the generation of vortexes and to smoothen the flow of fluid. In this manner, in a case in which a fluid flows along the shape in which the contour shape of the other end surface is larger than the contour shape of the one end surface, the flow velocity of the fluid is different between the one and the other of the tubular portion, and in an elastic fluid, the density becomes more different. Therefore, since the inside surface or the outside surface of the tubular portion which is in contact with the fluid has a strong interaction with the fluid, particularly, disturbance of the fluid easily arises. In the tubular portion of the fluid flow straightening member of the present invention, since the contour shape of the other end surface is larger than the contour shape of the one end surface, and the outermost ceramic fiber layer covering the outside and/or the inner ceramic fiber layer which is the inside layer of the support material is oriented along the central axis, it is possible to make it difficult to generate a disturbance in the flow of the fluid. Therefore, it is possible to favorably use the fluid flow straightening member of the present invention as piping, a flying object and a propelling body which moves inside a fluid, or the like.

(5) The ceramic fiber layer is configured by arranging a plurality of strands which are obtained by bundling the ceramic fibers.

When the fluid flow straightening member of the present invention is used in a form of a strand in which a plurality of ceramic fibers are bundled, since the plurality of fibers are gathered, it is possible to reduce fuzzing in which individual fibers protrude. Therefore, it is possible to further suppress disturbances of the airflow, and it is possible to reduce the resistance.

(6) The ceramic matrix is SiC.

Since SiC is excellent in corrosion resistance and oxidation resistance and has high strength, by using SiC for the ceramic matrix, it is possible to favorably use the fluid flow straightening member even in a high temperature and corrosive atmosphere.

(7) The ceramic fibers are SiC fibers.

Since SiC fiber is excellent in corrosion resistance and oxidation resistance and has high strength, by using SiC as a support material, even in a case in which the ceramic matrix is damaged by a high temperature and corrosive atmosphere, the ceramic fibers stop the development of cracks, and it is possible to safely use the support material.

(8) The central axis is disposed in a flow direction of a fluid.

By disposing the central axis in the flow direction of the fluid, the tubular portion which surrounds the central axis is also disposed in the flow direction of the fluid, so that the flow of the fluid is not disturbed.

### Advantageous Effects of Invention

According to the present invention, an outermost ceramic fiber layer of a fluid flow straightening member is configured by ceramic fibers which are oriented along the central axis.

Therefore, according to the present invention, since undulations which obstruct the flow of fluid are not easily formed and disturbances in the fluid do not easily arise, it is possible to obtain a fluid flow straightening member having a structure in which disturbances of air flow do not arise easily.

### BRIEF DESCRIPTION OF DRAWINGS

FIG. 1(A) is a process diagram illustrating a winding process of ceramic fibers by hoop winding in a manufacturing method of a fluid flow straightening member according to the present invention, FIG. 1(B) and FIG. 1(C) are process diagrams illustrating winding processes of the ceramic fibers by helical winding in the manufacturing method of the fluid flow straightening member, and FIG. 1(D) is a process diagram illustrating an axial direction disposition process of the ceramic fibers.

FIG. 2(A) is a sectional diagram illustrating a state in which a support material which serves as a tubular portion is formed around a core material, and FIG. 2(B) is a sectional diagram illustrating a state in which a tubular portion is formed by removing a core material.

FIG. 3(A) is a perspective view of the fluid flow straightening member of a first embodiment, and FIG. 3(B) is a side surface view of one ceramic fiber as viewed from a C direction in FIG. 3(A).

FIG. 4 is a perspective diagram of a fluid flow straightening member of a second embodiment.

FIG. 5(A) is a sectional diagram illustrating a state in which a support material which serves as a tubular portion and a cap portion is formed around a core material in a third embodiment, and FIG. 5(B) is a sectional diagram illustrating a state in which a tubular portion and a cap portion are formed by removing a core material.

FIG. 6 illustrates a manufacturing process of a fluid flow straightening member of an embodiment of the present invention, where FIG. 6(A) illustrates a manufacturing process in which manufacturing is carried out in the order of a support material forming process, a matrix forming process, and a core removing process, FIG. 6(B) illustrates a manufacturing process in which manufacturing is carried out in the order of the support material forming process, the core removing process, and the matrix forming process, and FIG. 6(C) illustrates a manufacturing process in which manufacturing is carried out in the order of the support material forming process, the matrix forming process, the core removing process, and the matrix forming process.

FIG. 7 illustrates a detailed manufacturing process of the support material forming process of the fluid flow straightening member of the embodiment of the present invention, where FIG. 7(A) illustrates a manufacturing process in which an axial direction disposition process is performed first and last, FIG. 7(B) illustrates a manufacturing process in which the axial direction disposition process is performed first, and FIG. 7(C) illustrates a manufacturing process in which the axial direction disposition process is performed last.

FIG. 8 is an application example of the fluid flow straightening member of the embodiment of the present invention, specifically, FIG. 8 is an application example to a gas flow straightening member of a silicon single crystal pulling apparatus.

### DESCRIPTION OF EMBODIMENTS

Description will be given of a fluid flow straightening member of the present invention and a manufacturing method of the fluid flow straightening member.

The fluid flow straightening member of the present invention for solving the problem is a fluid flow straightening member including a tubular portion which surrounds a central axis, wherein the tubular portion includes a support material which includes an inner ceramic fiber layer and an outermost ceramic fiber layer, and a ceramic matrix which covers the support material, and wherein the outermost ceramic fiber layer which covers an outside and/or an inside of the inner ceramic fiber layer is configured by ceramic fibers which are oriented along the central axis.

The outermost ceramic fiber layer of the fluid flow straightening member is configured by the ceramic fibers which are oriented along the central axis. Therefore, since undulations which obstruct the flow of the fluid are not easily formed and a disturbance does not easily arise in the fluid, it is possible to reduce resistance.

Here, the flow of the fluid refers to a case in which a fluid moves relative to the fluid flow straightening member, and includes a case in which a fluid flows relative to the fluid flow straightening member and a case in which the fluid flow straightening member moves in the fluid.

According to the fluid flow straightening member of the present invention, since it is possible to reduce the unevenness which becomes a resistance of the air flow without processing the surface, it is possible to sufficiently exhibit the strength of a support material without cutting the ceramic fibers, and a high-strength fiber-reinforced ceramic composite material is obtained.

Favorable aspects of the fluid flow straightening member of the present invention will be described hereinafter.

(1) An angle between the ceramic fiber which configure the outermost ceramic fiber layer and a plane including the central axis is 0° to 20°.

Therefore, in the fluid flow straightening member of the present invention, when the angle between the plane including the central axis and the ceramic fiber is 0° to 20°, the air flow is capable of smoothly flowing along the ceramic fibers.

Further, since the unevenness caused by the thickness of the ceramic fiber is stretched in the direction of the central axis by greater than or equal to 1/sin 20° times (2.92 times), it is possible to reduce disturbance of the fluid and it is possible to reduce resistance.

The angle between the ceramic fiber which configure the outermost ceramic fiber layer and the plane including the central axis is defined by using a plane including a straight line which connects the central axis and the ceramic fiber at the shortest distance.

(2) Both end portions of the tubular portion along the central axis are opened.

Since both end portions of the tubular portion along the central axis are opened, it is possible to allow the fluid to smoothly flow along the outer circumferential surface and the inner circumferential surface of the tubular portion. Therefore, the fluid flow straightening member of the present invention can be used as piping through the inner portion of which a fluid flows, a flying object and a propelling body which moves inside a fluid, or the like.

(3) The outermost ceramic fiber layer which covers the outside of the inner ceramic fiber layer is oriented along the central axis, and at least one of both end portions of the tubular portion along the central axis includes a cap portion and is closed.

In the fluid flow straightening member of the present invention, since the outermost ceramic fiber layer which covers the outside of the inner ceramic fiber layer is oriented along the central axis, and at least one of both end portions of the tubular portion along the central axis includes the cap portion and is closed, it is possible to allow the fluid to smoothly flow along the outer circumferential surface of the tubular portion. Therefore, it is possible to use the fluid flow straightening member of the present invention as a flying object and the like which moves inside a fluid.

(4) A contour shape of another end surface of the tubular portion is larger than a contour shape of one end surface of the tubular portion.

Since the tubular portion has a shape in which the contour shape of the other end surface is larger than the contour shape of the one end surface, the fluid flow straightening member of the present invention has a shape similar to, for example, a cone, a truncated cone, a spheroid, or the like. Since the sectional area of such a shape smoothly changes, it is possible to suppress the generation of vortexes and to smoothen the flow of fluid. In this manner, in a case in which a fluid flows along the shape in which the contour shape of the other end surface is larger than the contour shape of the one end surface, the flow velocity of the fluid is different between the one and the other of the tubular portion, and in an elastic fluid, the density becomes more different. Therefore, since the inside surface or the outside surface of the tubular portion which is in contact with the fluid has a strong interaction with the fluid, particularly, disturbance of the fluid easily arises. In the tubular portion of the fluid flow straightening member of the present invention, since the contour shape of the other end surface is larger than the contour shape of the one end surface, and the outermost ceramic fiber layer covering the outside and/or the inner ceramic fiber layer which is the inside layer of the support material is oriented along the central axis, it is possible to make it difficult to generate a disturbance in the flow of the fluid. Therefore, it is possible to favorably use the fluid flow straightening member of the present invention as piping, a flying object and a propelling body which moves inside a fluid, or the like.

(5) The ceramic fiber layer is configured by arranging a plurality of strands which are obtained by bundling the ceramic fibers.

When the fluid flow straightening member of the present invention is used in a form of a strand in which a plurality of ceramic fibers are bundled, since the plurality of fibers are gathered, it is possible to reduce fuzzing in which individual fibers protrude. Therefore, it is possible to further suppress disturbances of the airflow, and it is possible to reduce the resistance.

(6) The ceramic matrix is SiC.

Since SiC is excellent in corrosion resistance and oxidation resistance and has high strength, by using SiC for the ceramic matrix, it is possible to favorably use the fluid flow straightening member even in a high temperature and corrosive atmosphere.

(7) The ceramic fibers are SiC fibers.

Since SiC fiber is excellent in corrosion resistance and oxidation resistance and has high strength, by using SiC as a support material, even in a case in which the ceramic matrix is damaged by a high temperature and corrosive atmosphere, the ceramic fibers stop the development of cracks, and it is possible to safely use the support material.

(8) The central axis is disposed in a flow direction of a fluid.

By disposing the central axis in the flow direction of the fluid, the tubular portion which surrounds the central axis is also disposed in the flow direction of the fluid, so that the flow of the fluid is not disturbed.

Hereinafter, the first embodiment of the present invention will be described.

The manufacturing method of the fluid flow straightening member of the present invention includes a support material forming process, a matrix forming process, and a core removing process. First, after forming the support material, the core removing process and the matrix forming process are performed. The order of the core removing process and the matrix forming process is not particularly limited, and the matrix forming process may be performed before or after the core removing process.

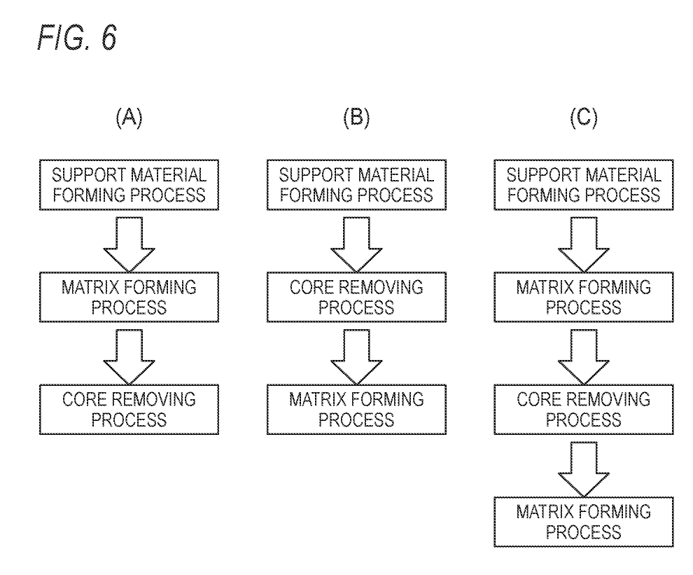

FIGS. 6(A) to 6(C) illustrate the manufacturing process of the fluid flow straightening member of the first embodiment of the present invention. FIG. 6(A) illustrates the manufacturing process in which manufacturing is carried out in the order of the support material forming process, the matrix forming process, and the core removing process, FIG. 6(B) illustrates the manufacturing process in which manufacturing is carried out in the order of the support material forming process, the core removing process, and the matrix forming process, and FIG. 6(C) illustrates a manufacturing process in which manufacturing is carried out in the order of the support material forming process, the matrix forming process, the core removing process, and the matrix forming process.

Next, the support material forming process will be described. In the support material forming process, the ceramic fibers are wound around the core material and the support material is formed. The support material forming process is finely classified by the disposition, the winding method, and the like of the ceramic fibers. The support material forming process includes a winding process and an axial direction disposition process. The winding process further includes a helical winding process and a hoop winding process.

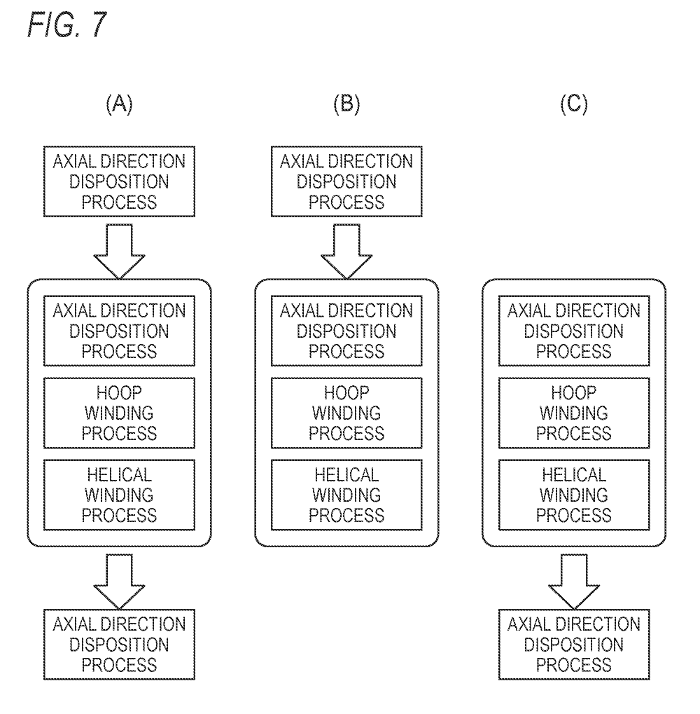

FIGS. 7(A) to 7(C) illustrate the detailed manufacturing process of the support material forming process of the fluid flow straightening member of the first embodiment of the present invention.

FIG. 7(A) illustrates a manufacturing process in which the axial direction disposition process is performed first and last. According to this manufacturing method, the fluid flow straightening member can be configured by the outermost ceramic fiber layer which covers the outside and the inside of the inner ceramic fiber layer and is configured by ceramic fibers which are oriented along the central axis.

FIG. 7(B) illustrates a manufacturing process in which the axial direction disposition process is performed first but not last. According to this manufacturing method, the fluid flow straightening member can be configured by the outermost ceramic fiber layer which covers the inside surface of the inner ceramic fiber layer and is configured by ceramic fibers which are oriented along the central axis.

FIG. 7(C) illustrates a manufacturing process in which the axial direction disposition process is performed last and not first. According to this manufacturing method, the fluid flow straightening member can be configured by the outermost ceramic fiber layer which covers the outside of the inner ceramic fiber layer and is configured by ceramic fibers which are oriented along the central axis. During the direction disposition process which is performed first or last, the arrangement, winding method, number and order of the ceramic fibers are not limited and may be freely combined.

Next, the matrix forming process will be described. In the matrix forming process, the periphery of the ceramic fibers which are the aggregate is filled with the ceramic matrix.

Any ceramic matrix may be used, and the ceramic matrix is not particularly limited. For example, it is possible to use SiC, alumina, Si₃N₄, B₄C, and the like. The ceramic matrix may be formed using any method. For example, it is possible to use a precursor method of thermally decomposing an organic precursor (precursor) to obtain a matrix of ceramics, a CVD method of thermally decomposing a raw material gas to obtain a ceramic matrix, and the like. These may also be used in combination.

Hereinafter, the precursor method and the CVD method will be described.

In the precursor method, a precursor from which a ceramic is obtained by thermal decomposition is selected, as appropriate. In the precursor method, a support body is coated or impregnated with a liquid precursor, is subsequently subjected to heating treatment, and is finally fired to obtain a ceramic matrix. In the heating treatment, various processes are performed according to the form of the precursor. In a case in which the precursor is a solution, drying of the solvent is carried out, in a case in which the precursor is a monomer, a dimer, an oligomer, or the like, a polymerization reaction is carried out, and in a case in which the precursor is a polymer, a thermal decomposition reaction process is carried out.

The precursor is used in the form of a liquid. The term “liquid” can be used as a solution of a precursor in a solvent, a liquid precursor, a liquid-state precursor obtained by heating and melting a solid precursor, and the like. In the precursor method, the precursor is finally fired to produce a ceramic matrix.

As the precursor, for example, the following can be used. In a case in which the precursor is carbon, it is possible to use a phenol resin, a furan resin, or the like. In a case in which the precursor is SiC, it is possible to use polycarbosilane (PCS: Polycarbosilane) or the like. It is possible to obtain a ceramic matrix by allowing these resins to infiltrate between the ceramic fibers and carrying out thermal decomposition.

In the precursor method, it is possible to use the precursor as a binder for preventing detachment and fuzzing of the ceramic fibers in a case in which the axial direction disposition process is performed last in the support material forming process and the ceramic fibers which are lined up in the axial direction are in the outermost layer. In this case, since it is possible to maintain a state in which the ceramic fibers are bonded to each other in the process of drying, polymerizing, or thermally decomposing the precursor, the precursor can be favorably used.

In the CVD method, the support material is placed in a CVD furnace, and the raw material gas is introduced in a heated state. The raw material gas diffuses inside the CVD furnace, and when the raw material gas comes into contact with the heated support material, thermal decomposition occurs, and a ceramic matrix corresponding to the raw material gas is formed on the surface of the ceramic fibers which configure the support material.

The raw material gas which is used in the CVD method is selected, as appropriate, according to the type of the ceramic matrix.

In a case in which the target ceramic matrix is carbon, it is possible to use a hydrocarbon gas such as methane, ethane, propane, or the like.

In a case in which the target ceramic matrix is SiC, it is possible to use a mixed gas of a hydrocarbon gas and a silane-based gas, an organic silane-based gas including carbon and silicon, or the like. For these raw material gases, it is also possible to use a gas in which hydrogen is substituted with halogen. For the silane-based gas, in the cases of chlorosilane, dichlorosilane, trichlorosilane, tetrachlorosilane, and organosilane-based gases, it is possible to use methyltrichlorosilane (methyltrichlorosilane), methyldichlorosilane (methyldichlorosilane), methylchlorosilane (methylchlorosilane), dimethyldichlorosilane (dimethyldichlorosilane), trimethyldichlorosilane (trimethyldichlorosilane) and the like. These raw material gases may be appropriately mixed and used, and also used as a carrier gas such as hydrogen, argon, or the like. In a case in which hydrogen is used as the carrier gas, the carrier gas can participate in the adjustment of equilibrium.

In a case of other ceramic materials, it is possible to appropriately select the raw material gas according to the target ceramic matrix.

The temperature of the CVD can be appropriately selected according to the decomposition temperature and the decomposition rate of the raw material gas, and is, for example, 800° C. to 2000° C. The pressure of the CVD can be appropriately selected according to the state of deposition of the ceramic matrix. A usable range is, for example, a low pressure CVD method of 0.1 to 100 kPa, or an atmospheric pressure CVD method in which the pressure is not controlled.

Next, the core removing process will be described.

Three patterns exist according to the position of the core removing process.

In a case in which the core removing process is after the matrix forming process, the manufacturing is carried out in the order of the support material forming process, the matrix forming process, and the core removing process (FIG. 6(A)).

In a case in which the core removing process is before the matrix forming process, the manufacturing is carried out in the order of the support material forming process, the core removing process, and the matrix forming process (FIG. 6(B)).

In a case in which the core removing process is in the middle of the matrix forming process, the manufacturing is carried out in the order of the support material forming process, the matrix forming process, the core removing process, and the matrix forming process (FIG. 6(C)).

As illustrated in FIG. 6(A), in a case in which the core removing process is after the matrix forming process, the ceramic fiber-reinforced ceramic composite material is already formed at the stage of being separated in the core removing process, which is the fluid flow straightening member of the present invention. In this case, since the core removing is carried out at the stage at which the shape is fixed, it is possible to obtain the fluid flow straightening member with high dimensional precision.

As illustrated in FIG. 6(B), in the case of the core removing process before the matrix forming process, a support material which is formed of a ceramic fiber layer is separated in the core removing process. In this case, it is possible to form the ceramic matrix on the inside surface and the outside surface of the support material at the same time, and it is possible to efficiently obtain the fluid flow straightening member.

As illustrated in FIG. 6(C), in a case in which the core removing process is in the middle of the matrix forming process, at the stage of being separated in the core removing process, the product is a ceramic fiber-reinforced ceramic composite material which has not been completely formed. In this case, it is possible to form the ceramic matrix on the inside surface and the outside surface of the support material at the same time, and it is possible to efficiently obtain the fluid flow straightening member with high dimensional precision.

Although any of the methods may be used, it is preferable to use the manufacturing method in which the core removing process is in the middle of the matrix forming process.

In the case in which the core removing process is in the middle of the matrix forming process, since the core material is removed after the ceramic matrix is formed between the ceramic fibers of the support body to become the ceramic fiber-reinforced ceramic composite material, it is possible to ensure that deformation does not occur easily after the core material is removed.

In this case, since it is possible to form the ceramic matrix from both sides of the outside surface and the inside surface of the support body after the core material is removed, it is possible to reliably cover the ceramic fibers with the ceramic matrix, fraying does not occur easily, and it is possible to obtain a more rigid ceramic fiber-reinforced ceramic composite material.

In the case in which the core removing process is in the middle of the matrix forming process, the same method may be used for the matrix forming process before and after the core removing process, and different methods may also be used. In particular, it is preferable to use the precursor method before the core removing process, and to use the CVD method after the core removing process. In the precursor method, it is possible to harden the support body using a simple method, and it is possible to prevent deformation. In the CVD method, since it is possible to obtain a dense and strong film, it is possible to favorably use the film as a film which configures the outermost surface of the fluid flow straightening member.

### First Embodiment

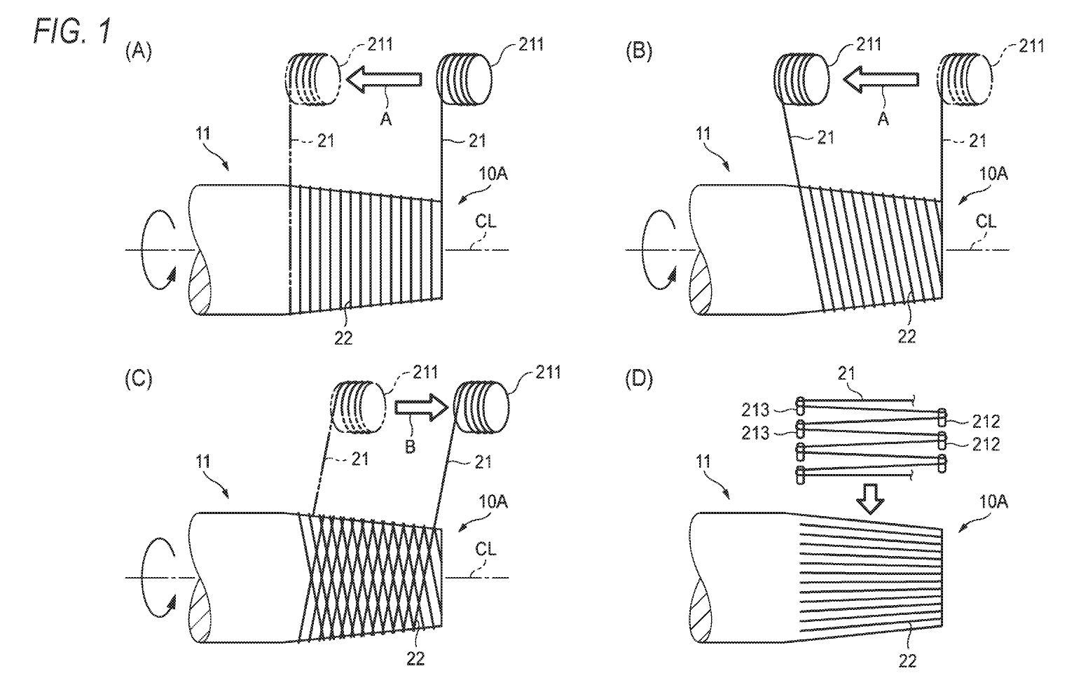

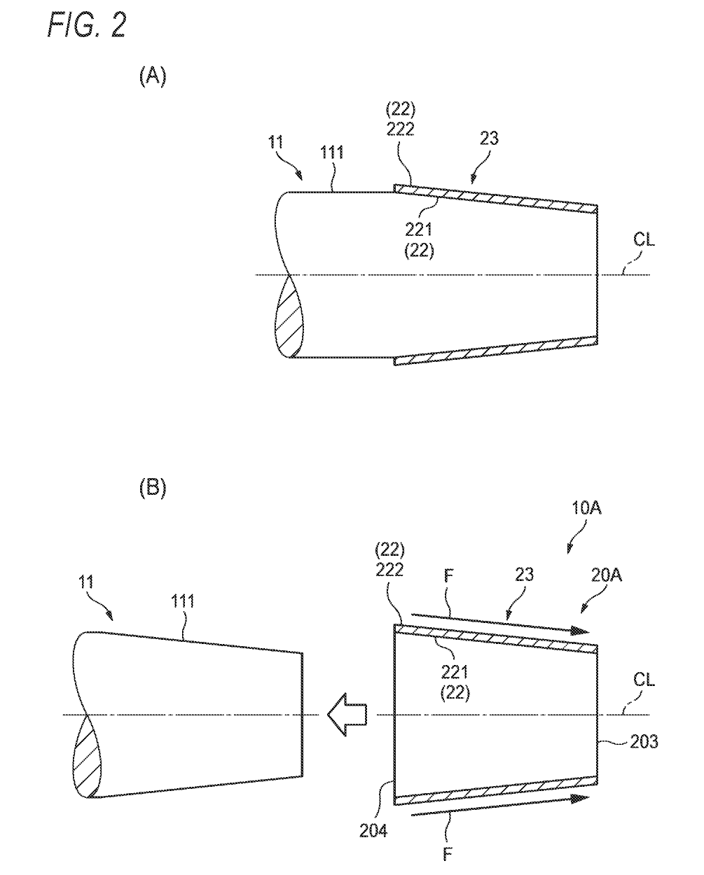

The manufacturing method of the fluid flow straightening member will be described based on FIGS. 1(A) to 1(D) and FIGS. 2(A) and 2(B).

The manufacturing method of a fluid flow straightening member 10A includes a winding process of winding ceramic fibers 21 along the circumferential direction with respect to a central axis CL of a core material 11 which is formed in a columnar shape, and an axial direction disposition process of disposing the ceramic fibers 21 parallel to the central axis CL of the core material 11.

In the winding process, as illustrated in FIGS. 1(A), 1(B) and 1(C), the ceramic fibers 21 are wound around the outer circumferential surface of the core material 11 which rotates around the central axis CL to form a ceramic fiber layer 22.

FIG. 1(A) illustrates the winding process of the ceramic fibers 21 by hoop winding, FIG. 1(B) illustrates a forward path of the winding process of the ceramic fibers 21 by helical winding, and FIG. 1(C) illustrates a forward path of the winding process of the ceramic fibers 21 by helical winding.

At this time, it is possible to wind the ceramic fibers 21 around the outside surface of the core material 11 by moving (refer to arrow A) rolls 211 which store the ceramic fibers 21 from one end side (the right end side in FIGS. 1(A) and 1(B)) of the core material 11 to the other end side (the left end side in FIGS. 1(A) and 1(B)).

In the forward path of the winding process of the ceramic fibers 21 by the helical winding illustrated in FIG. 1(C), the rolls 211 which store the ceramic fibers are moved from the other end side (the left end side in FIG. 1(C)) of the core material 11 to the one end side (the right end side in FIG. 1(C)) (refer to arrow B).

Here, to be exact, the ceramic fibers 21 are wound in a spiral shape also in the winding process of the ceramic fibers 21 by hoop winding. The form of the ceramic fiber 21 which is wound is changed according to the feed speed of the rolls 211. The winding method of feeding the rolls 211 by the amount covered with the ceramic fibers 21 and winding the ceramic fibers 21 in a looped manner is referred to as hoop winding, and the winding method of feeding the rolls 211 such that the ceramic fibers 21 are spaced from each other and winding the ceramic fibers 21 in a spiraled manner is referred to as helical winding.

In the hoop winding, the feed speed of the rolls 211 is approximately the same as the thickness of the ceramic fibers 21, and it is possible to form the ceramic fiber layer 22 by covering almost the entire outer circumferential surface of the core material 11 with the ceramic fibers 21 by feeding in one direction.

On the other hand, in helical winding, since it is not possible to cover the entire outer circumferential surface of the core material 11 in a single feeding, the ceramic fiber layer 22 is formed on the outer circumferential surface of the core material 11 while repeatedly feeding the rolls 211 back and forth. In a case where the unidirectional feeding of the ceramic fibers 21 is defined as one unit, in a case in which the hoop winding is repeated, the ceramic fiber 21 of an arbitrary unit has a contact point with each unit of ceramic fiber 21 in front and behind thereof.

On the other hand, in the helical winding, since it is not possible to cover the entire outer circumferential surface of the core material 11 with one unit of the ceramic fiber 21, an arbitrary unit of the ceramic fiber 21 is in contact with a plurality of units of the ceramic fibers 21 in front and behind thereof.

In a case in which the ceramic fiber layer 22 is a combination of hoop winding and helical winding, there are many contact points of the ceramic fibers 21 crossing each other at the interface, and it is possible to obtain a ceramic fiber-reinforced ceramic composite material with high strength.

In the drawings, to facilitate understanding, the interval between the adjacent ceramic fibers 21 is shown in an enlarged manner.

The fluid flow straightening member 10A of the first embodiment is configured by the ceramic fibers 21 in which the outermost ceramic fiber layer 22 which covers the outside of the inner ceramic fiber layer of a tubular portion 20A is oriented along the central axis CL. In order to obtain such the tubular portion 20A, the uppermost layer of the tubular portion 20A is formed by forming the ceramic fiber layer 22 using the axial direction disposition process.

In the axial direction disposition process, for example, as illustrated in FIG. 1(D), engaging portions 212 and 213 are provided on one end side and the other end side of the core material 11, and the ceramic fibers 21 are disposed along the central axis CL of the core material 11 to form the ceramic fiber layer 22 by hooking the ceramic fibers 21 alternately on the engaging portion 212 and the engaging portion 213. This is carried out on the entire circumference along the outside surface of the core material 11. At this time, depending on the thickness and the disposition of the locking portions 212, 213, the ceramic fibers 21 may be disposed obliquely with respect to the plane including the central axis CL. However, since the ceramic fibers 21 which are adjacent to each other are extremely close, it can be said that the ceramic fibers 21 are disposed parallel to the central axis CL. In FIG. 1(D), to facilitate understanding, the interval between the adjacent ceramic fibers 21 is shown in an enlarged manner.

Before the uppermost layer is formed, the winding process and the axial direction disposition process are carried out repeatedly to laminate the ceramic fiber layer 22. The order of the winding process and the axial direction disposition process and the number of times of execution are arbitrary.

For example, it is possible to carry out the winding process and the axial direction disposition process alternately once each, and it is also possible to carry out the winding process and the axial direction disposition process alternately a plurality of times each. There are helical winding and hoop winding in the winding process. Therefore, it is possible to laminate the ceramic fiber layer 22 while selecting, as appropriate, from the three processes of the winding process by helical winding(the helical winding process), the winding process by hoop winding (the hoop winding process), and the axial direction disposition process, thereby configuring the tubular portion 20A (refer to FIG. 7).

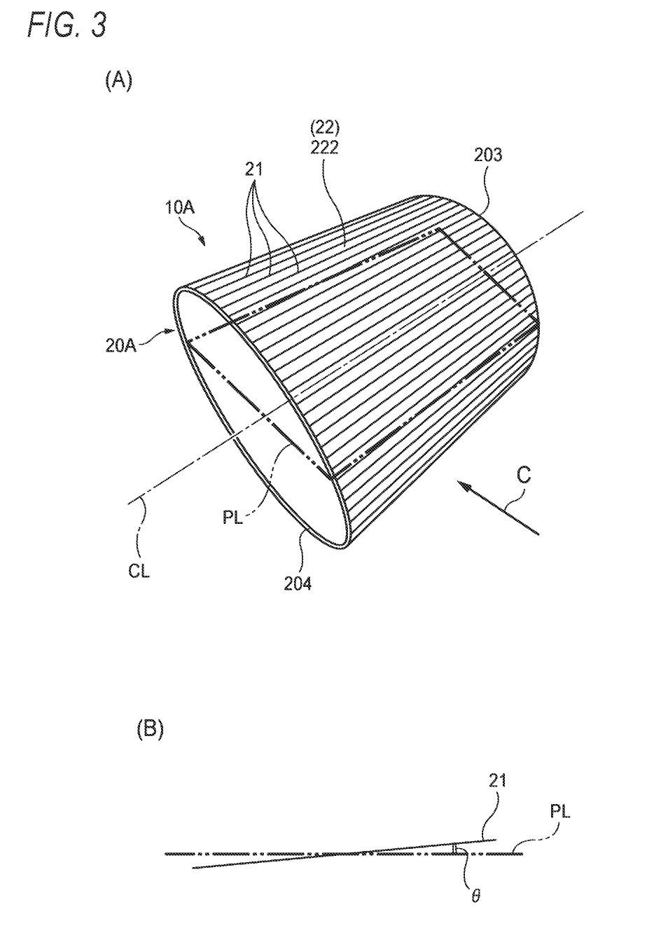

Accordingly, a plurality of the ceramic fiber layers 22 are deposited to form a tubular base member 23 in which the support material is formed on the surface of the core material (refer to FIG. 2(A)). At this time, in an outermost ceramic fiber layer 222 which is farthest from a side surface 111 of the core material 11 in the base member 23, the base member 23 is manufactured such that the ceramic fibers 21 are provided along a plane PL (refer to FIG. 3) including the central axis CL.

Next, a ceramic matrix is formed between the ceramic fibers 21 of the support body to form the tubular portion 20A which surrounds the central axis CL. In the first embodiment, the ceramic matrix is formed using the CVD method. A support material which includes the ceramic fiber layer 22 is placed in a CVD furnace, and methyltrichlorosilane gas is introduced into the CVD furnace to form a ceramic matrix of SiC.

As illustrated in FIG. 2(B), in the separating process, the tubular portion 20A is released from the core material 11, the tubular portion 20A is fired, and the fluid flow straightening member 10A is manufactured.

The configuration is not limited thereto, and the process of separating the tubular portion 20A from the core material 11 may be either before forming the ceramic matrix, after forming the ceramic matrix, or at an in-progress stage of forming the ceramic matrix (refer to FIG. 6).

Here, a case in which both end surfaces along the central axis CL of the tubular portion 20A are opened is illustrated. However, also in a case in which one end surface is closed, the manufacturing may be performed in the same manner.

When one end surface is closed, for example, it is possible to use a method of depositing a ceramic matrix using the base member 23 which includes the tubular portion 20A and a cap portion, a method of combining the cap portion later, or the like.

Next, the fluid flow straightening member 10A will be described.

As illustrated in FIG. 3(A), the fluid flow straightening member 10A includes the tubular portion 20A which surrounds the central axis CL. It is possible to use the fluid flow straightening member 10A, for example, by disposing the central axis CL in the flow direction of the fluid (refer to arrow F in FIG. 2(B)).

It is possible to form the contour shape of another end surface 204 of the tubular portion 20A to be larger than the contour shape of one end surface 203 of the tubular portion 20A. The one end surface 203 and the other end surface 204 of the tubular portion 20A are opened. The tubular portion 20A may have a cylindrical shape with both ends opened (not illustrated).

The tubular portion 20A includes the base member 23 (refer to FIG. 2) in which the ceramic fiber layer (the ceramic fibers) 22, which is formed of a support material and includes the ceramic fibers 21 which are SiC fibers, is laminated, and it is possible to deposit a ceramic matrix on the ceramic fibers 21 using the CVD method to obtain the fiber-reinforced ceramic composite material. It is possible to use strands in which the ceramic fibers are bundled as the ceramic fiber 21.

The outermost ceramic fiber layer (the outermost layer) 222 of the tubular portion 20A is the ceramic fiber layer 22 which is formed such that the ceramic fibers are provided along the virtual plane PL including the central axis CL.

Here, an angle θ between the virtual plane PL including the central axis CL and the ceramic fibers 21 (the support material) is 0° to 20°.

In other words, as illustrated in FIG. 3(A), when the cross section of the tubular portion 20A which is cut by the virtual plane PL including the central axis CL is viewed along the plane PL (refer to arrow C in FIG. 3(A)), as illustrated in FIG. 3(B), the ceramic fiber 21 intersects the plane PL at the angle θ.

Next, the effects of the fluid flow straightening member 10A of the first embodiment will be described.

According to the fluid flow straightening member 10A of the first embodiment, in the outermost ceramic fiber layer 222 which configures the tubular portion 20A of the fluid flow straightening member 10A, the ceramic fibers 21 are oriented in a direction along the plane PL including the central axis CL which is surrounded by the tubular portion 20A.

Therefore, since undulations which obstruct the flow of the fluid are not easily formed and a disturbance does not easily arise in the fluid, it is possible to reduce resistance.

Further, since it is possible to reduce unevenness which becomes resistance of air flow without cutting the ceramic fibers 21 which are the surface of the fluid flow straightening member 10A, it is possible to sufficiently exhibit the strength of the ceramic fibers 21, and a high-strength fiber-reinforced ceramic composite material is obtained.

Further, since the fluid flow straightening member 10A is not formed by scraping out, a decrease in strength due to cutting of the fibers does not arise.

According to the fluid flow straightening member 10A of the first embodiment, when the angle θ between the plane PL including the central axis CL and the ceramic fibers is 0° to 20°, the air flow is capable of smoothly flowing along the ceramic fibers 21.

Since the unevenness caused by the thickness of the ceramic fibers 21 is stretched in the direction of the central axis CL by greater than or equal to 1/sin 20° times (2.92 times), it is possible to reduce disturbance of the fluid and it is possible to reduce resistance.

According to the fluid flow straightening member 10A of the first embodiment, in a case in which both end portions of the tubular portion 20A along the central axis CL are opened, it is possible to allow the fluid to flow along the outer circumferential surface and the inner circumferential surface of the tubular portion 20A, and it is possible to straighten the flow of the fluid. Therefore, the fluid flow straightening member 10A can be used as piping or a flying object which moves inside a fluid.

According to the fluid flow straightening member 10A of the first embodiment, since the contour shape of the other end surface of the tubular portion 20A is larger than the contour shape of the one end surface of the tubular portion 20A, the shape of the tubular portion 20A resembles a cone, a truncated cone, or the like, for example.

Further, in a case in which the one end surface 203 with a small end surface contour shape is not opened, it is possible to reduce the resistance caused by the outermost ceramic fiber layer 222 of the tubular portion 20A in the fluid which flows relatively from the one end surface 203. In a case in which the one end surface 203 is also opened, since it is possible to allow the fluid to flow along the outermost ceramic fiber layer 222 and an innermost ceramic fiber layer 221 of the tubular portion 20A, it is possible to reduce the resistance of the fluid which flows along the outer circumferential surface and the inner circumferential surface. Therefore, it is possible to use the fluid flow straightening member 10A as piping or a flying object which moves inside the fluid.

According to the fluid flow straightening member 10A of the first embodiment, when the ceramic fibers 21 are used in a form of a strand in which a plurality of ceramic fibers are bundled, since a plurality of fibers are gathered, it is possible to reduce fuzzing in which individual fibers protrude. Therefore, it is possible to further suppress disturbance of air flow, and it is possible to reduce the resistance.

According to the fluid flow straightening member 10A of the first embodiment, the ceramic matrix is SiC.

Since SiC is excellent in corrosion resistance and oxidation resistance and has high strength, by using SiC for the ceramic matrix, it is possible to favorably use the fluid flow straightening member even in a high temperature and corrosive atmosphere.

According to the fluid flow straightening member 10A of the first embodiment, the ceramic fibers are SiC fibers.

Since SiC fibers are excellent in corrosion resistance and oxidation resistance and have high strength, by using SiC as a support material, even in a case in which the ceramic matrix is damaged by a high temperature and corrosive atmosphere, it is possible to safely use the support material.

According to the fluid flow straightening member 10A of the first embodiment, the central axis CL is disposed in the flow direction of the fluid.

By disposing the central axis CL in the flow direction of the fluid, the tubular portion 20A which surrounds the central axis CL is also disposed in the flow direction of the fluid, so that it is possible to reduce the resistance of the fluid.

According to the manufacturing method of the fluid flow straightening member of the first embodiment, in the winding process, the ceramic fibers 21 are wound along the circumferential direction with respect to a central axis CL of the core material 11 which is formed in a columnar shape, and in the axial direction disposition process, the ceramic fibers 21 are disposed parallel to the central axis CL of the core material 11. In this manner, the base member 23 of the tubular portion 20A is formed by the plurality of ceramic fiber layers 22.

Next, the ceramic matrix is formed so as to infiltrate between the ceramic fibers 21 of the base member 23.

Any ceramic matrix may be used, and the ceramic matrix is not particularly limited. For example, it is possible to use SiC, alumina, Si₃N₄, B₄C, and the like. The ceramic matrix may be formed using any method. For example, it is possible to use a precursor method of thermally decomposing an organic precursor (a precursor) to obtain a matrix of ceramics, a CVD method of thermally decomposing a raw material gas to obtain a ceramic matrix, and the like.

Hereinafter, the precursor method and the CVD method will be described.

In the precursor method, a precursor from which a ceramic may be obtained using thermal decomposition is selected, as appropriate. In the precursor method, a support body is coated or impregnated with a liquid precursor, is subsequently subjected to heating treatment, and the ceramic matrix is obtained. In the heating treatment, various processes are performed according to the form of the precursor.

In a case in which the precursor is a solution, drying of the solvent is carried out, in a case in which the precursor is a monomer, a dimer, an oligomer, or the like, a thermal decomposition reaction is carried out after a polymerization reaction, and in a case in which the precursor is a polymer, a thermal decomposition reaction process is carried out.

The precursor is used in the form of a liquid. The term “liquid” can be used as a solution of a precursor in a solvent, a liquid precursor, a liquid-state precursor obtained by heating and melting a solid precursor, and the like. In the precursor method, the precursor is finally fired to produce a ceramic matrix.

In the CVD method, the support material is placed in a CVD furnace, and the raw material gas is introduced in a heated state. The raw material gas diffuses inside the CVD furnace, and when the raw material gas comes into contact with the heated support material, thermal decomposition occurs, and a ceramic matrix corresponding to the raw material gas is formed on the surface of the ceramic fibers which configure the support material.

Next, the tubular portion 20A is released from the core material 11. Accordingly, it is possible to manufacture the fluid flow straightening member.

### Second Embodiment

Next, the second embodiment will be described.

The same reference numerals are given to parts which are common with the fluid flow straightening member 10A of the above-described first embodiment, and redundant description will be omitted.

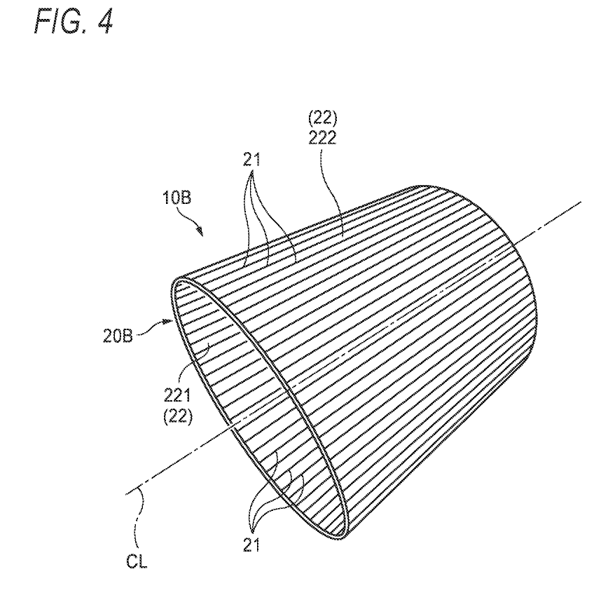

As illustrated in FIG. 4, in a fluid flow straightening member 10B of the second embodiment, the innermost ceramic fiber layer 221 and the outermost ceramic fiber layer 222 of a tubular portion 20B become the ceramic fiber layer 22 which is formed such that the ceramic fibers are provided along the virtual plane PL (refer to FIG. 3(A)) including the central axis CL.

Accordingly, since undulations which obstruct the flow of the fluid are not easily formed and a disturbance does not easily arise in the fluid, the resistance can be reduced. Here, the flow of the fluid refers to a case in which a fluid moves relative to the fluid flow straightening member 10B, and includes a case in which a fluid flows relative to the fluid flow straightening member 10B and a case in which the fluid flow straightening member 10B moves in the fluid.

It is possible to use the manufacturing method which is described in the first embodiment as the manufacturing method of the fluid flow straightening member 10B. This can be obtained by performing the axial direction disposition process first and last in the support material forming process.

### Third Embodiment

Next, the third embodiment will be described.

The same reference numerals are given to parts which are common with the fluid flow straightening member 10A of the first embodiment and the fluid flow straightening member 10B of the second embodiment which are described above, and redundant description will be omitted.

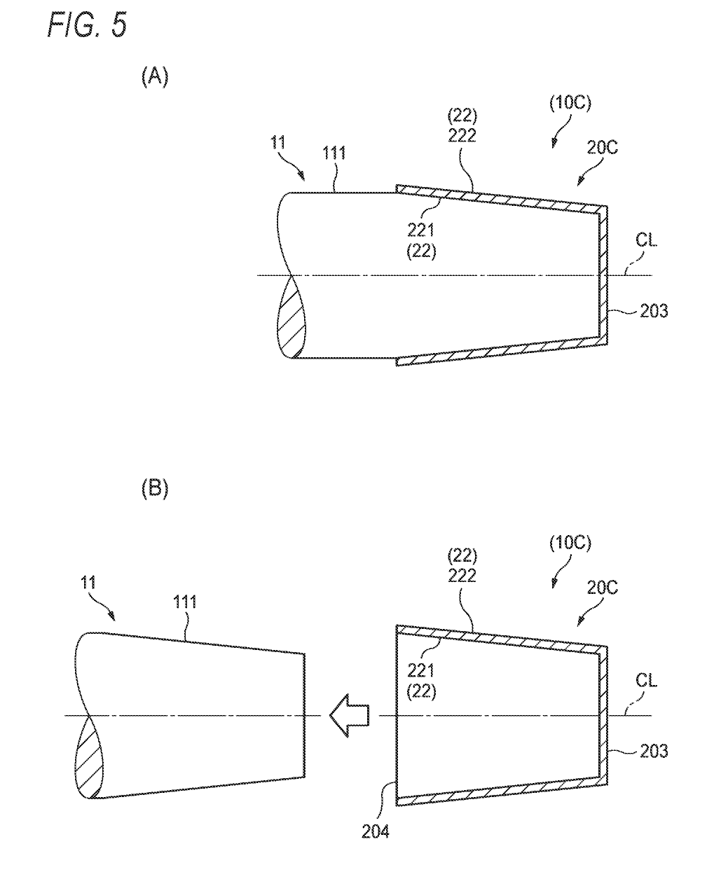

As illustrated in FIGS. 5(A) and 5(B), in a fluid flow straightening member 10C of the third embodiment, a cap portion is provided on the one end surface 203 of a tubular portion 20C, and the tubular portion 20C is not penetrated in the central axis CL direction. Therefore, in the tubular portion 20C, it is sufficient for only the ceramic fibers of the outermost ceramic fiber layer 222 to become the ceramic fiber layer 22 which is formed along the virtual plane PL (refer to FIG. 3(A)) including the central axis CL. It is also possible to form ceramic fibers of the innermost ceramic fiber layer (the outermost layer) 221 to be along the virtual plane PL (refer to FIG. 3(A)) including the central axis CL.

Accordingly, since undulations which obstruct the flow of the fluid are not easily formed and a disturbance does not easily arise in the fluid, the resistance can be reduced.

It is possible to use the manufacturing method which is described in the first embodiment as the manufacturing method of the fluid flow straightening member 10C.

The fluid flow straightening member of the present invention is not limited to the above-described embodiments, and it is possible to carry out appropriate modifications, improvements, and the like.

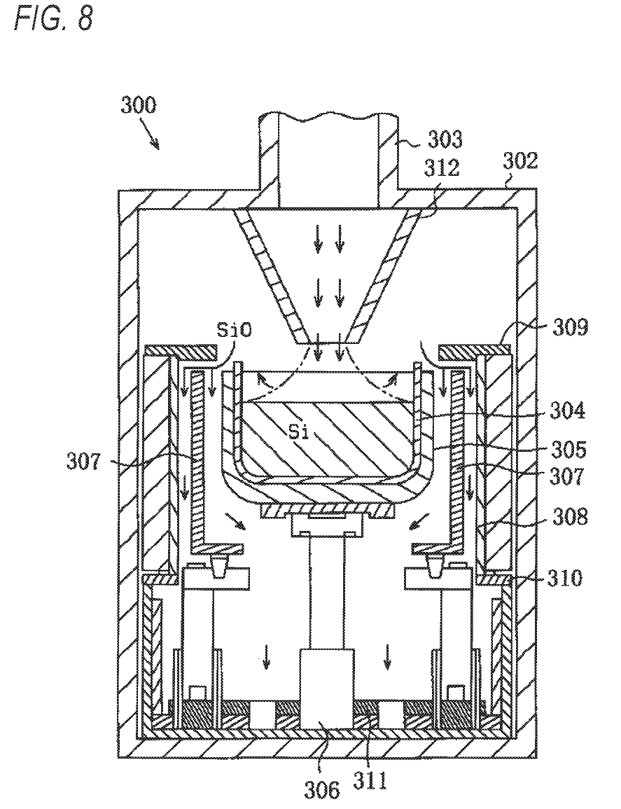

FIG. 8 is an application example of the fluid flow straightening member which is described in the embodiments of the present invention, specifically, FIG. 8 is an application example to a gas flow straightening member 312 of a silicon single crystal pulling apparatus 300.

The silicon single crystal pulling apparatus 300 illustrated in FIG. 8 is for obtaining a high purity silicon ingot by heating and melting the silicon material once and subsequently pulling up the silicon as a single crystal.

An introduction portion 303 for introducing an inert gas into an inner portion of a hermetic body 302 is provided on the top portion of the hermetic body 302 which configures the silicon single crystal pulling apparatus 300. A quartz crucible 304, a crucible 305, a rotating shaft 306, a heater 307, a heat insulating cylinder 308, an upper ring 309, a lower ring 310, a bottom heat shielding plate 311, the gas flow straightening member 312 (the fluid flow straightening member), and the like are stored in the inner portion of the hermetic body 302.

The quartz crucible 304 into which the silicon material is placed is held in the crucible 305 which is disposed outside of the quartz crucible 304. The central portion of the bottom surface of the crucible 305 is supported from below by the rotating shaft 306. When the rotating shaft 306 rotates due to driving means which is not illustrated, the crucible 305 rotates accordingly. The crucible 305 is heated by the heater 307 which is disposed around the side portion of the crucible 305 such that the silicon material melts. The heat insulating cylinder 308 which is provided around the side portion of the heater 307 is supported between the upper ring 309 and the lower ring 310. The bottom heat shielding plate 311 for preventing heat from escaping from the bottom surface is disposed on the inner bottom surface of the hermetic body 302.

The gas flow straightening member 312 is a tapered member with a tapered shape, and the end portion of the large diameter side is fixed to the inside of the top surface of the hermetic body 302 in a state in which the end portion on the small diameter side faces downward.

It is also possible to apply the fluid flow straightening member of the present invention to such gas flow straightening member 312 of the silicon single crystal pulling apparatus 300.

The present application is based on Japanese Patent Application (Japanese Patent Application No. 2014-228830) filed on Nov. 11, 2014, the contents of which are hereby incorporated by reference.

### INDUSTRIAL APPLICABILITY

It is possible to use the fluid flow straightening member of the present invention in fluid piping, the exterior of a fluid flow straightening member, a nozzle of a burner, or the like, and in the manufacture thereof.

### REFERENCE SIGNS LIST

10A, 10B, 10C fluid flow straightening member

11 core material

20A, 20B, 20C tubular portion

203 one end surface (both end portions)

204 other end surface (both end portions)

21 ceramic fiber

22 ceramic fiber layer

221 innermost ceramic fiber layer (outermost layer)

222 outermost ceramic fiber layer (outermost layer)

23 base member

CL central axis

PL plane

1. A fluid flow straightening member comprising a tubular portion which surrounds a central axis,
wherein the tubular portion includes a support material which includes an inner ceramic fiber layer and an outermost ceramic fiber layer, and a ceramic matrix which covers the support material, and
wherein the outermost ceramic fiber layer which covers at least one of an outside and an inside of the inner ceramic fiber layer is configured by ceramic fibers which are oriented along the central axis.

2. The fluid flow straightening member according to claim 1,
wherein an angle between the ceramic fiber which configure the outermost ceramic fiber layer and a plane including the central axis is 0° to 20°.

3. The fluid flow straightening member according to claim 1,
wherein both end portions of the tubular portion along the central axis are opened.

4. The fluid flow straightening member according to claim 1,
wherein the outermost ceramic fiber layer which covers the outside of the inner ceramic fiber layer is oriented along the central axis, and
wherein at least one of both end portions of the tubular portion along the central axis includes a cap portion and is closed.

5. The fluid flow straightening member according to claim 1,
wherein a contour shape of another end surface of the tubular portion is larger than a contour shape of one end surface of the tubular portion.

6. The fluid flow straightening member according to claim 1,
wherein the ceramic fiber layer is configured by arranging a plurality of strands which are obtained by bundling the ceramic fibers.

7. The fluid flow straightening member according to claim 1,
wherein the ceramic matrix is SiC.

8. The fluid flow straightening member according to claim 1,
wherein the ceramic fibers are SiC fibers.

9. The fluid flow straightening member according to claim 1,
wherein the central axis is disposed in a flow direction of a fluid.
